(19) United States
(12) Patent Application Publication
(10) Pub. No.: US 2010/0134101 A1
(43) Pub. Date: Jun. 3, 2010

(54) BROAD-RANGE MAGNETIC SENSOR AND MANUFACTURING PROCESS THEREOF

(75) Inventors: CATERINA RIVA, Cusago (IT); Marco Morelli, Bareggio (IT); Marco Marchesi, Borgonovo val Tidone (IT)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics S.r.l., Agrate Brianza (mi) (IT)

(21) Appl. No.: 12/628,448

(22) Filed: Dec. 1, 2009

(30) Foreign Application Priority Data
Dec. 3, 2008 (IT) TO2008A000897

(51) Int. Cl. G01R 33/06

(52) U.S. Cl. 324/251

(57) ABSTRACT

A magnetic sensor is formed by a fluxgate sensor and by at least one Hall sensor integrated in a same integrated device, wherein the magnetic core of the fluxgate sensor is formed by a magnetic region that operates also as a concentrator for the Hall sensor. The magnetic region is manufactured in a post-machining stage on the metallization layers wherein the energizing coil and sensing coil of the fluxgate sensor are formed; the energizing and sensing coils are formed on a semiconductor substrate housing the conductive regions of the Hall sensor.

### CROSS REFERENCE TO RELATED APPLICATIONS

This application claims the priority benefit of Italian patent application number TO2008A000897, filed on Dec. 3, 2008, entitled “BROAD-RANGE MAGNETIC SENSOR AND MANUFACTURING PROCESS THEREOF,” which is hereby incorporated by reference to the maximum extent allowable by law.

### BACKGROUND OF THE INVENTION

1. Field of the Invention

The present invention relates to a broad-range magnetic sensor and a corresponding manufacturing process.

2. Discussion of the Related Art

Among high-sensitivity magnetic-field sensors capable of detecting low-intensity magnetic fields, the magnetic sensor known as a fluxgate sensor offers the best compromise between cost and performance (see, for example, the planar fluxgate sensor described in U.S. Pat. No. 6,404,192). In practice, a planar fluxgate sensor comprises a magnetic core, of a generally elongated shape, overlying an energizing coil. By supplying the energizing coil with an appropriate a.c. excitation current, it is possible to bring the magnetic core into a series of cycles of magnetic saturation. Sensing of external fields is obtained via a pair of sensing coils, generally set underneath the ends of the magnetic core.

For a better understanding, reference is made to FIG. 1, which shows a fluxgate sensor 1 with double sensitivity axis, of the type described in the aforementioned US patent. The fluxgate sensor 1 comprises an energizing coil 2 overlying four sensing coils 3a, 3b, 3c and 3d and underlying a magnetic core 4. In detail, the energizing coil 2 is generally square-shaped, and the magnetic core 4 is cross-shaped and includes a first arm 4a and a second arm 4b, perpendicular to one another. The sensing coils 3a-3d are set in pairs, with vertical axes passing in the proximity of the ends of the arms 4a, 4b of the magnetic core 4, with the sensing coils 3a, 3b aligned to one another and parallel to a first diagonal of the energizing coil 2 and to the axis of the first arm 4a, and the sensing coils 3c, 3d aligned to one another and parallel to a second diagonal of the energizing coil 2 and to the axis of the second arm 4b.

Considering initially only the first arm 4a and the sensing coils 3a, 3b, if the energizing coil is supplied with an appropriate excitation current, able to cause saturation of the magnetic material at an appropriate frequency, the two halves of the first arm 4a are magnetized in opposite directions, as is shown by the arrows 7 in FIG. 1. In the absence of an applied external magnetic field, the two sensing coils 3a, 3b experience two equal and zero induced voltages, if they have been connected in a differential configuration.

Instead, if an external magnetic field is applied (arrow H in FIG. 1), a first half of the first arm 4a (in the case shown, the left half in the drawing) is magnetized in the same direction as the external field M, thus amplifying its own total magnetization, whereas a second half of the first arm 4a (here, the half on the right in the drawing) is magnetized in an opposite direction, and its total magnetization is reduced. It follows that the differential voltage of the sensing coils 3a, 3b is non-zero and is amplitude modulated by the intensity of the external field M.

The presence of the second arm 4b of the magnetic core enables detection of magnetic fields having a direction perpendicular to the external field M and bestows upon the magnetic sensor 1 two sensitivity axes.

With the fluxgate technology it is possible to provide sensors able to measure d.c. or slowly variable magnetic fields, of an intensity comprised between a few μG and a few G, with a high resolution, of the order of nG. In terms of dynamic range and resolution, the fluxgate devices fall between Hall-effect magnetic-field sensors (which are typically able to detect fields comprised between 10 G and 10⁶ G) and SQUIDs (Superconducting Quantum Interference Devices, which are typically able to detect fields comprised between 10⁻¹⁰ and 10⁻⁵ G).

For low values of the magnetic field, fluxgate sensors are preferable to Hall-effect sensors on account of their better performance, and find a wider application as compared to SQUID sensors, thanks to their lower cost and encumbrance. Thus, fluxgate sensors could find application in either portable or non-portable systems where Hall sensors do not have a sufficient sensitivity.

However, in order to continue to exploit the widespread knowledge of the technologies for the production of Hall sensors, there exist solutions in which an attempt has been made to extend the sensitivity of Hall sensors to the range of fluxgate sensors, exploiting the addition, to a Hall sensor, of magnetic material (or concentrator, see, for example, U.S. Pat. No. 6,545,462; U.S. Pat. No. 6,184,679 and U.S. Pat. No. 7,235,968).

These solutions, however, still do not enable the same performance that can be obtained via the fluxgate sensors.

One aim of the present invention is thus to provide a magnetic sensor that overcomes the limitations of known sensors.

According to at least one embodiment of the invention there is provided a magnetic sensor, the corresponding manufacturing process, a magnetometer, and an electronic apparatus.

According to another embodiment of the invention, there is provided a magnetic sensor, comprising a fluxgate sensor and a Hall sensor integrated in the same integrated device.

According to another embodiment of the invention, there is provided a process for manufacturing a magnetic sensor, comprising the step of forming a fluxgate sensor and a Hall sensor in the same integrated device.

In one embodiment the present sensor is formed by the superposition of a fluxgate sensor and of a Hall sensor provided with a concentrator, and the magnetic core of the fluxgate sensor also forms a concentrator for the Hall-effect sensor.

### BRIEF DESCRIPTION OF THE DRAWINGS

For a better understanding of the present invention, an embodiment thereof is now described, purely by way of non-limiting example, with reference to the attached drawings, wherein:

FIG. 1 is a perspective top plan view of a fluxgate sensor with two sensitivity axes;

FIG. 2 is a cross-sectional view of an embodiment of a magnetic sensor according to the invention;

FIGS. 3-7 are cross-sectional views through the present magnetic sensor, in successive manufacturing steps;

FIG. 8 shows a block diagram of a magnetometer including the magnetic sensor of FIG. 2;

FIG. 9 shows a possible application of the magnetometer of FIG. 7; and

FIG. 10 shows a block diagram of an electronic apparatus including the magnetometer of FIG. 7.

### DETAILED DESCRIPTION

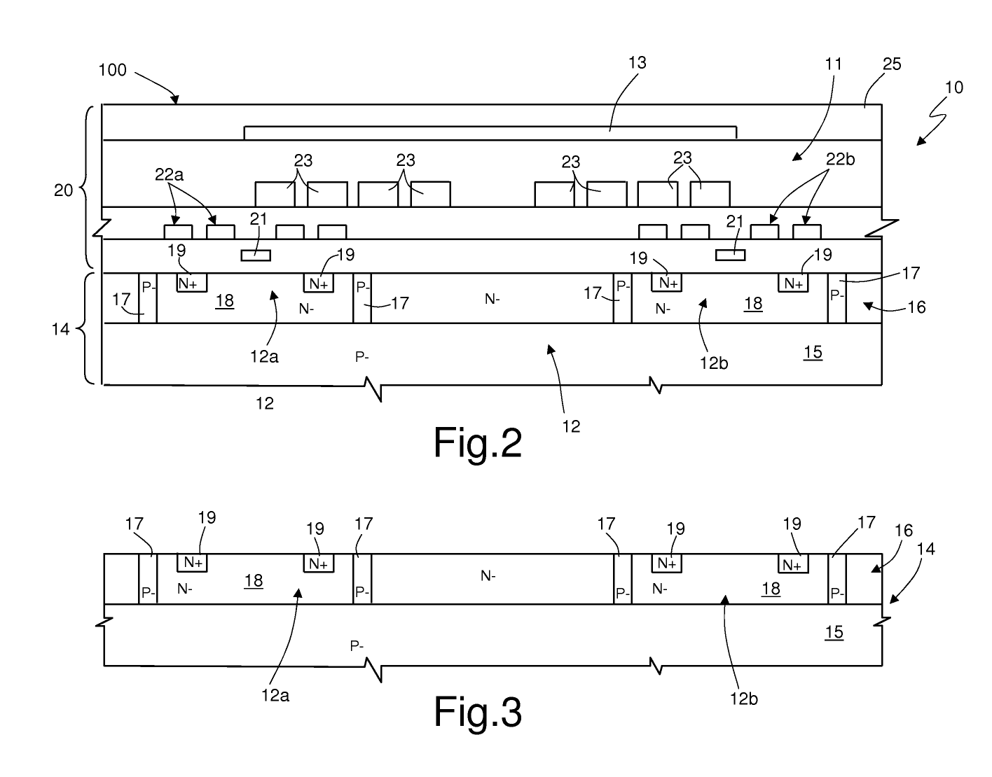

FIG. 2 shows a possible embodiment of a magnetic sensor 10, obtained using a CMOS technology and comprising a fluxgate sensor 11 and a Hall sensor 12.

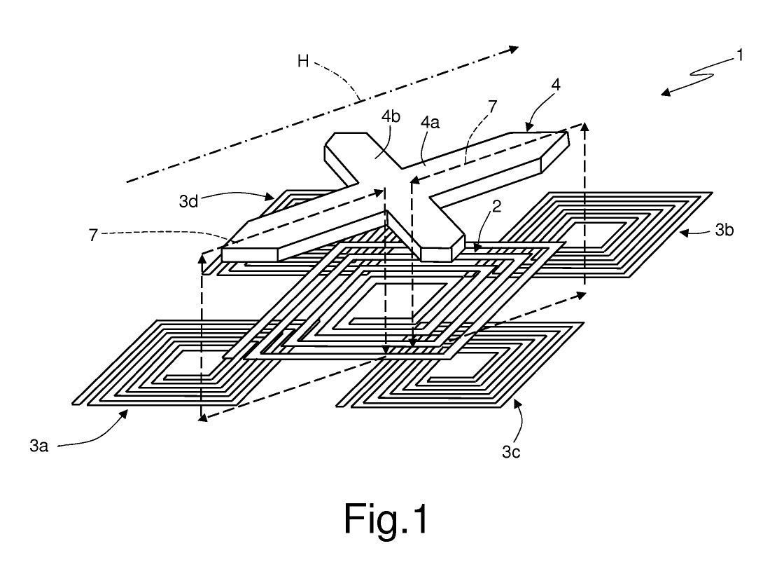

The fluxgate sensor 11 is, for example, obtained as the fluxgate sensor of FIG. 1 and comprises a magnetic region 13 having a cross shape and forming both the magnetic core of the fluxgate sensor and a concentrator for the Hall sensor 12. In the example illustrated, the Hall sensor 12 is formed by four Hall-effect cells, two for each arm of the magnetic region 13 forming the magnetic concentrator. In the figure, only two Hall-effect cells 12a, 12b are visible, set underneath a first arm of the magnetic region 13, corresponding to the first arm 4a of FIG. 1. Two further Hall-effect cells (not visible) are set underneath a second arm of the magnetic region 13, corresponding to the second arm 4b of FIG. 1. All the Hall-effect cells (the cells 12a, 12b and the non-visible ones) are integrated in a single chip 100.

In detail, in the embodiment of FIG. 2, a body 14 of semiconductor material comprises a substrate 15, of a P⁻ type, and an epitaxial layer 16, of an N⁻ type. The epitaxial layer 16 houses the Hall-effect cells 12a, 12b, separated from one another by insulation regions 17 of a P⁻ type, which delimit active regions 18 accommodating conductive regions 19 of an N⁺ type, as well as further conductive sensing regions (not visible in FIG. 2). In addition, the epitaxial layer 16 may also house, in a way not shown, further components forming supply/control circuitries of the sensors 11, 12 and/or further circuits functionally associated to the magnetic sensor 10.

An insulating material layer 20 extends on the body 14 and is formed by a plurality of layers arranged on top of one another and embedding the fluxgate sensor 11. In particular, the fluxgate sensor 11 is formed in three metallization levels and by the magnetic region 13. In detail, a first metallization level forms connection lines 21, a second metallization level forms sensing coils (here only two are visible, designated by 22a and 22b), and a third metallization level forms an energizing coil 23.

The connection lines 21 are connected, through plugs (not illustrated), to the sensing coils 22a, 22b and enable electrical connection thereof to a supply/control circuitry (not shown), for example, integrated in the epitaxial layer 16. Similar connection lines (not shown) may enable connection of the energizing coil 2 to the respective supply/control circuitry.

The magnetic region 13 is made of a ferromagnetic material having the following characteristics:
a low value of saturation magnetization Bₛₐₜ so as to require a low power to bring the material into saturation; for example, Bₛₐₜ can have a value of approximately 0.5 T;
a high value of permeability up to the frequency of operation of the device integrating the magnetic sensor 10; for example, the relative permeability μᵣ can be equal to 35,000 at 100 kHz.

In particular, if the magnetic region 13 is made of NiFe (permalloy), it has a saturation magnetization Bₛₐₜ of 1 T and a relative permeability of approximately 3,500 at 500 MHz. Alternatively, NiFeMo or other appropriately developed dedicated magnetic alloys can be used.

A passivation layer 25 extends on the magnetic region 13.

In practice, the presence of the Hall sensor 12 underneath the fluxgate sensor 11 enables exploitation of the magnetic region 13 for measuring magnetic fields having an intensity greater than the upper limit of the range of sensitivity of the fluxgate sensor 11, extending the sensitivity of the resulting magnetometer.

In fact, as is known, operation of the Hall-effect cells 12 is based upon detection of the Hall voltage between pairs of conductive regions extending in a direction transverse to the conductive regions 19, as a result of the interaction between a current flowing between the conductive regions 19 themselves and an external magnetic field, orthogonal to the current and, in the case considered, to the surface of the body 14. The magnetic region 13 acts here as concentrator and has the purpose of modifying the lines of magnetic flux of an external magnetic field parallel or co-planar to the surface of the body 14 so that the lines of flux traverse vertically the Hall-effect cells 12 arranged underneath the ends of the magnetic region 13, in addition to providing amplification. In this way, a magnetic field parallel or co-planar to the surface of the body 14 becomes detectable by the Hall-effect cells 12, as is, for example, described in Christian Shott et al., “A CMOS Single-Chip Electronic Compass with Microcontroller”, 2007 IEEE International Solid-State Circuit Conference, ISSCC 2007/SESSION 21/SENSORS AND MEMS/21.2.

The magnetic sensor 10 of FIG. 2 is manufactured as described hereinbelow.

Initially (FIG. 3), junctions N and P intended to form the insulation regions 17, the conductive regions 19, and possible other regions envisaged by the magnetic sensor 10, are implanted and diffused in the epitaxial layer 16, in a per se known manner.

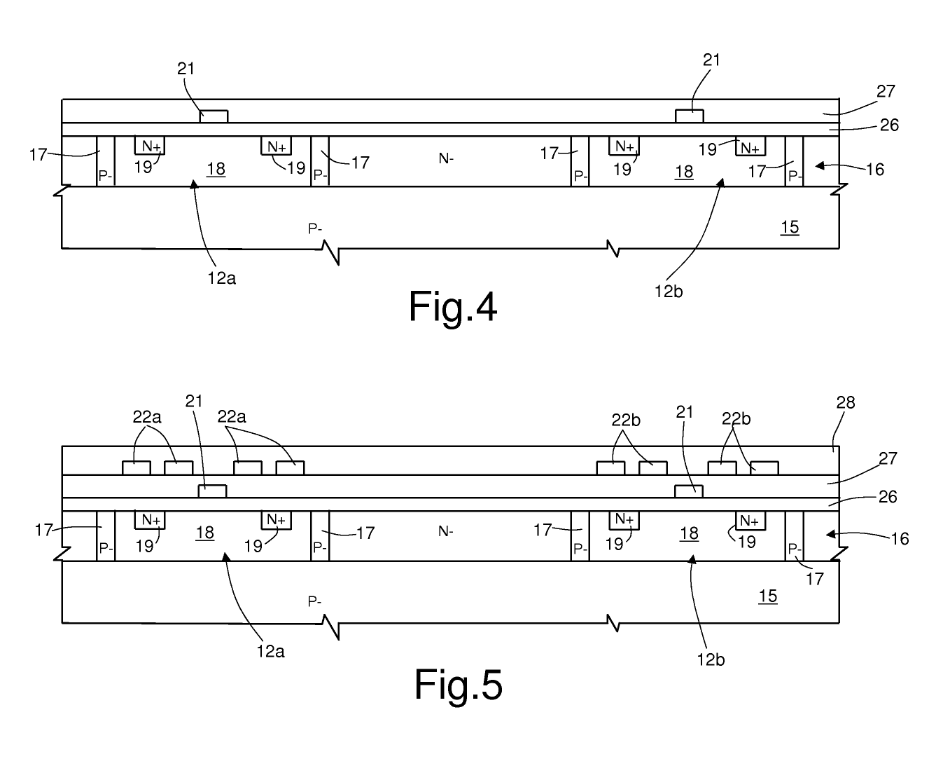

Then (FIG. 4), a first dielectric layer 26 is deposited; plugs are formed (not illustrated; for example, they may be of metal) to contact the conductive regions formed in the body 14, in particular with the conductive regions 19; a first metal layer is deposited and defined for providing connection lines 21 and possible further first-level connections envisaged by the device; a second dielectric layer 27 is deposited, and plugs are formed (not illustrated; for example, they may be of metal) to contact the connection lines 21.

Next (FIG. 5), a second metal layer is deposited and defined, to provide the sensing coils 22a, 22b and possible further second-level metal connection regions; a third dielectric layer 28 is deposited, and plugs are formed (not illustrated; for example, they may be made of metal) to contact the energizing coil 23.

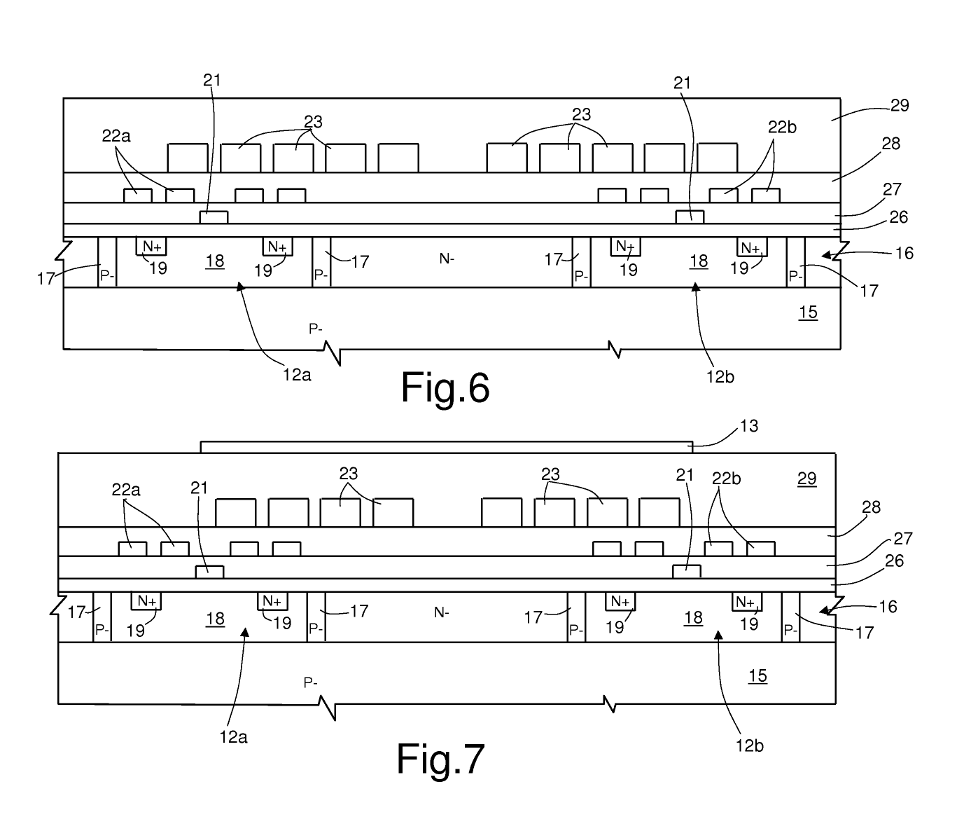

Then (FIG. 6), a third metal layer is deposited and defined to obtain the energizing coil 23, and a fourth dielectric layer 29 is deposited.

Next (FIG. 7), via a post-machining process, the magnetic material which is to form the magnetic region 13 is deposited.

The magnetic material is deposited via sputtering so as to obtain a typical thickness around 1-5 μm. The sputtering technique (see, for example, Andrea Baschirotto et al., “An integrated microFluxgate sensor with sputtered ferromagnetic core”, IMTC 06), enables provision of amorphous thin films with the indicated thickness so as to require a lower power consumption in order to saturate as compared to thicker layers deposited with other techniques (for example, by electroplating).

Finally, the deposited ferromagnetic layer is defined so as to have the cross shape, and the passivation layer 25 is deposited so as to cover the magnetic region 13, in order to obtain the structure of FIG. 2.

The sensor described herein has numerous advantages. In fact, it represents a device capable of operating on the set of ranges of sensitivity of a fluxgate sensor and of a Hall sensor with magnetic concentrator, greatly extending the possible applications of the resulting magnetometer.

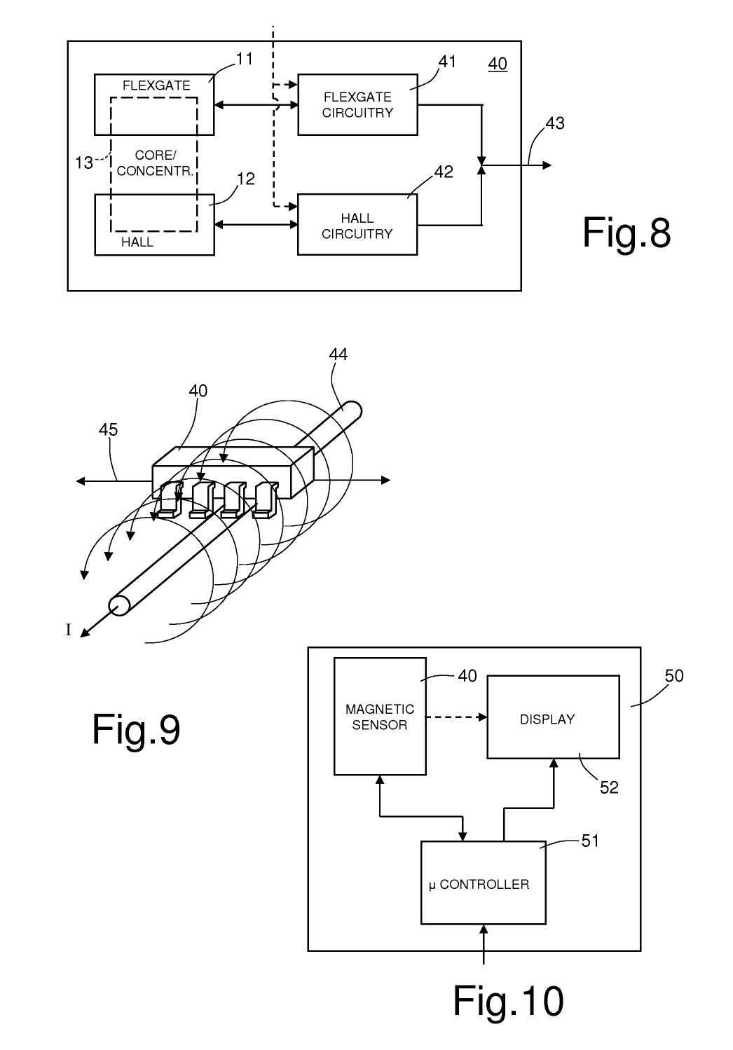

The magnetic sensor 10 can be integrated alone or be integrated in the same chip with the respective supply/control circuitries. FIG. 8 shows, for example, a block diagram of a magnetometer 40, comprising the fluxgate sensor 11, the Hall sensor 12, a fluxgate supply/control circuitry 41, and a Hall supply/control circuitry 42. In the diagram of FIG. 8, dashed arrows represent possible external control signals for controlling, if desired, selective turning-on of the fluxgate portion and/or of the Hall portion. The outputs of the circuitries 41, 42 are here connected to a single output 43 of the magnetometer. Alternatively or in addition, separate outputs may be envisaged.

The magnetometer 40 has a multiplicity of possible applications. For example, it can be used as current meter, as is shown in FIG. 9. In fact, by setting a wire 44 on or underneath the magnetometer 40, possibly oriented perpendicular to the sensitive axis 45 of the magnetometer 40 (if it has a single sensitivity axis), it is able to measure a current I flowing in the wire 44 without any resistive losses and without interrupting or interfering with operation of the circuit to which the wire 44 belongs. In this case, the output of the magnetometer 40 can be simply connected to an appropriate display (not shown).

The magnetometer 40 can also be used as electronic compass, for example, in a cellphone or other electronic apparatus having navigation functions. In this case, as is shown in FIG. 10, an apparatus 50 having navigation functions may comprise the magnetometer 40 and a microcontroller 51, which is connected with the magnetometer 40 and with a display 52 and receives control signals from outside through purposely provided interfaces (not illustrated).

Further possible applications comprise, among other things, apparatuses for detecting physiological parameters (heartbeat, cerebral waves, blood pressure, etc.), position detectors (whether linear or rotary, for example, for knobs, cursors, joysticks and the like, or mobile members, such as pistons, etc.), level indicators, and so on.

Finally, it is clear that modifications and variations can be made to the magnetic sensor and to the corresponding manufacturing process, described and illustrated herein, without thereby departing from the scope of the present invention, as defined in the annexed claims. For example, even though FIG. 2 shows a sensor including two Hall-effect cells, wherein each Hall-effect cell is arranged at a respective end of the magnetic region 13, the sensor could be obtained by increasing the number of cells arranged at each end of the magnetic region 13, and/or in an intermediate position. In addition, the shape of the core/concentrator can differ from the one illustrated; for example, the fluxgate sensor can have a single sensitivity axis with a single arm, and/or each arm may have a different shape, with the Hall-effect cells arranged underneath the ends of the magnetic region; the configuration and number of the sensing coils could be different; for example, a single sensing coil or a pair of sensing coils not in differential configuration could be provided. Alternatively, it is possible to provide two sensing coils arranged vertically on top of one another, wherein the underlying coil is used as feedback to increase the range of linearity and the sensitivity.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. A magnetic sensor, comprising a fluxgate sensor and a Hall sensor integrated in a same integrated device.

2. The magnetic sensor according to claim 1, wherein the fluxgate sensor comprises an energizing coil, at least one sensing coil and a magnetic core, and the Hall sensor comprises conductive regions and a magnetic concentrator, the magnetic sensor comprising a magnetic region forming both said magnetic core and said magnetic concentrator.

3. A magnetic sensor according to claim 2, wherein said integrated device comprises a body of semiconductor material integrating said conductive regions of the Hall sensor, and an insulating layer on said body, accommodating said energizing coil and said sensing coil, said magnetic region extending on said insulating layer, above said energizing and sensing coils and said conductive regions.

4. A magnetic sensor according to claim 3, wherein said energizing coil and sensing coils are formed in distinct metallization levels and said magnetic region is formed by a ferromagnetic material layer deposited by sputtering.

5. A magnetic sensor according to claim 3, wherein said magnetic region has an elongated structure provided with a first and a second ends, said fluxgate sensor comprises a first and a second sensing windings, and said Hall sensor comprises a first and a second Hall-effect cell, said first sensing winding and said first Hall-effect cell being arranged vertically under said first end, and said second sensing winding and said second Hall-effect cell being arranged vertically under said second end.

6. A process for manufacturing a magnetic sensor, comprising the step of:
forming a fluxgate sensor and a Hall sensor in a same integrated device.

7. A process according to claim 6, wherein the step of forming a fluxgate sensor and a Hall sensor comprises the steps of:
providing a body of semiconductor material;
forming conductive regions within said body;
forming an insulating layer on said body;
forming an energizing coil and a sensing coil in said insulating layer; and
forming a magnetic region on said insulating layer, above said energizing and sensing coils, and above said conductive regions, said magnetic region forming both a magnetic core for said fluxgate sensor and a magnetic concentrator for said Hall sensor.

8. A process according to claim 7, wherein the steps of forming an insulating layer, an energizing coil, and a sensing coil comprise:
depositing a dielectric layer;
depositing a metallization level;
defining said metallization level to obtain said sensing coil;
depositing a subsequent dielectric layer;
depositing a subsequent metallization level;
defining said subsequent metallization level to obtain said energizing coil;
depositing a further dielectric layer; and
depositing by sputtering said magnetic region.

9. A magnetometer, comprising the magnetic sensor according to claim 1, and including a supply/control circuitry for the fluxgate sensor and a supply/control circuitry for the Hall sensor.

10. A magnetometer according to claim 9, wherein said supply/control circuitries for the fluxgate sensor and the Hall sensor are integrated in said integrated device.

11. An electronic apparatus, comprising a control unit, a display, and a magnetometer according to claim 9.
